(19) United States
(12) Patent Application Publication
(10) Pub. No.: US 2022/0165575 A1
(43) Pub. Date: May 26, 2022

(54) METHOD OF FORMING STRUCTURES FOR THRESHOLD VOLTAGE CONTROL

(71) Applicant: ASM IP Holding B.V., Almere (NL)

(72) Inventors: Qi Xie, Wilsele (BE); Giuseppe Alessio Verni, Jodoigne (BE); Tatiana Ivanova, Helsinki (FI); Perttu Sippola, Helsinki (FI); Michael Eugene Givens, Oud-Heverlee (BE); Eric Shero, Phoenix, AZ (US); Jiyeon Kim, Tempe, AZ (US); Charles Dezelah, Helsinki (FI); Petro Deminskyi, Helsinki (FI); Ren-Jie Chang, Leuven (BE)

(21) Appl. No.: 17/529,562

(22) Filed: Nov. 18, 2021

Related U.S. Application Data
(60) Provisional application No. 63/117,250, filed on Nov. 23, 2020.

(51) Int. Cl. H01L 21/28; H01L 21/02; C23C 16/52; C23C 16/455

(52) U.S. Cl. CPC H01L 21/28194; H01L 21/02192; H01L 21/0228; C23C 16/305; C23C 16/52; C23C 16/45553; H01L 21/28185; H01L 21/02205

(57) ABSTRACT

Methods and systems for depositing threshold voltage shifting layers onto a surface of a substrate and structures and devices formed using the methods are disclosed. An exemplary method includes using a cyclical deposition process, depositing a threshold voltage shifting layer onto a surface of the substrate.

### CROSS-REFERENCE TO RELATED APPLICATIONS

This application claims priority to U.S. Provisional Patent Application Ser. No. 63/117,250 filed Nov. 23, 2020 titled METHOD OF FORMING STRUCTURES FOR THRESHOLD VOLTAGE CONTROL, the disclosure of which is hereby incorporated by reference in its entirety.

### FIELD OF INVENTION

The present disclosure generally relates to methods and systems suitable for forming a layer on a surface of a substrate and to structures including the layer. More particularly, the disclosure relates to methods and systems for forming layers that allow controlling the threshold voltage of metal-oxide-semiconductor field-effect transistors (MOSFETs) and to structures formed using the methods and systems.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes. For example, one challenge has been finding suitable dielectric stacks that form an insulating barrier between a gate and a channel of a field effect transistor. One particular problem in this regard is controlling the threshold voltage of field effect transistors.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming structures including threshold voltage shifting layers, to structures and devices formed using such methods, and to apparatus for performing the methods and/or for forming the structures and/or devices. The threshold voltage shifting layers can be used in a variety of applications, including reducing power consumption in integrated circuits. The presently described methods can comprise a cyclical deposition process. The cyclical deposition process can include one or more of an atomic layer deposition process and a cyclical chemical vapor deposition process. The cyclical deposition process can include a thermal process—i.e., a process that does not use plasma-activated species. In some cases, a reactant can be exposed to a plasma to form activated reactant species, e.g. radicals and/or ions.

Described herein is a method for depositing a threshold voltage shifting layer. In some embodiments, the method comprises providing a substrate in a reactor chamber. The substrate comprises a surface. The surface comprises a silicon oxide surface. The method further comprises depositing a threshold voltage shifting layer onto the silicon oxide surface by means of a cyclical deposition process. The threshold voltage shifting layer comprises an element selected from a lanthanide, yttrium, and scandium. The cyclical deposition process comprise one or more cycles. A cycle comprises providing a precursor to the reaction chamber in a precursor pulse; and providing a reactant to the reaction chamber in a reactant pulse. Thus, a threshold voltage shifting layer is formed on the substrate.

Further described herein is another embodiment of a method for depositing a threshold voltage shifting layer on a substrate. The method comprises providing a substrate within a reactor chamber. The substrate comprises a surface. The surface comprises a high-k dielectric surface. The method comprises depositing a threshold voltage shifting layer onto the high-k dielectric surface by means of a cyclical deposition process. The threshold voltage shifting layer comprises an element selected from a lanthanide, yttrium, and scandium. The cyclical deposition process comprises one or more cycles. A cycle comprises providing a precursor to the reaction chamber in a precursor pulse; and providing a reactant to the reaction chamber in a reactant pulse. Thus, a threshold voltage shifting layer on the substrate.

In some embodiments, the threshold voltage shifting layer comprises scandium, and the precursor comprises a scandium precursor.

In some embodiments, the scandium precursor comprises one or more cyclopentadienyl ligands and one or more amidinate ligands.

In some embodiments, the threshold voltage shifting layer comprises a scandium chalcogenide, and the reactant comprises a chalcogenide.

In some embodiments, the threshold voltage shifting layer comprises scandium oxide, and the reactant comprises an oxygen reactant selected from the list consisting of oxygen, ozone, hydrogen peroxide, and water.

In some embodiments, the oxygen reactant is water.

In some embodiments, the cyclical deposition process has a growth rate per cycle of 0.05 nm per cycle or less.

In some embodiments, the threshold voltage shifting layer comprises scandium sulfide, and the reactant comprises a sulfur reactant.

In some embodiments, the sulfur reactant is selected from the list consisting elemental sulfur, H₂S, an alkane thiol, an alkyl sulfide, and a dialkyl disulfide.

In some embodiments, the threshold voltage shifting layer comprises scandium selenide, and the reactant comprises a selenium reactant.

In some embodiments, the threshold voltage shifting layer comprises scandium telluride, and the reactant comprises a tellurium reactant.

In some embodiments, the threshold voltage shifting layer comprises scandium boride, and the reactant is a boron reactant.

In some embodiments, the boron reactant comprises borazine.

In some embodiments, the threshold voltage shifting layer comprises cerium, and the precursor comprises a cerium precursor.

In some embodiments, the cerium precursor is selected from the list consisting of cerium diketonates, cerium amidinates, cerium cyclopentadienyls, cerium alkoxides, and cerium alkylsilylamines.

In some embodiments, the cerium precursor comprises a cerium diketonate selected from the list consisting of: Ce(acac)₄, Ce(hfac)₄, Ce(thd)₄, and Ce(thd)₃phen.

In some embodiments, the cerium precursor comprises a cerium amidinate selected from the list consisting of Ce(iPrFMD)₃, Ce(iPr₂AMD)₃, and Ce(iPrCp)₂(iPr₂AMD).

In some embodiments, the cerium precursor comprises a cerium cyclopentadienyl selected from the list consisting of Ce(Cp)₃, Ce(EtCp)₃, and Ce(iPrCp)₃. In some embodiments, the cerium precursor comprises a substituted or unsubstituted cyclopentadienyl ligand. In some embodiments, the cerium precursor is selected from the list consisting of Ce(Cp)₃, Ce(EtCp)₃, Ce(MeCp)₃, Ce(nPrCp)₃, and Ce(nBuCp)₃.

In some embodiments, the cerium precursor comprises a cerium alkoxide.

In some embodiments, the cerium precursor comprises one or more cerium alkylsilylamines, the one or more cerium alkylsilylamines including Ce[N(SiMe₃)₂]₃.

In some embodiments, the threshold voltage shifting layer comprises a cerium chalcogenide, and the reactant is a chalcogenide reactant comprising a chalcogen.

In some embodiments, the threshold voltage shifting layer comprises cerium oxide, and the chalcogenide reactant is an oxygen reactant selected from the list consisting of H₂O, O₃, H₂O₂, O₂, oxygen radicals, and oxygen ions.

In some embodiments, the cerium chalcogenide comprises cerium sulfide, and the chalcogenide reactant comprises a sulfur reactant.

In some embodiments, the sulfur reactant is selected from elemental sulfur, H₂S, an alkane thiol, an alkyl sulfide, and a dialkyl disulfide.

In some embodiments, the threshold voltage shifting layer comprises cerium boride, and wherein the reactant comprises a boron reactant selected from the list consisting of hydroboranes; alkylboranes; haloboranes; and amines, ethers, alcohols, thiols, and dialkyl sulfides thereof.

In some embodiments, the boron reactant is selected from diborane and borazine.

In some embodiments, the threshold voltage shifting layer comprises yttrium, and the precursor comprises an yttrium precursor.

In some embodiments, the yttrium precursor comprises an alkyl-substituted cyclopentadienyl ligand and an amidinate ligand. In some embodiments, the yttrium precursor comprises a heteroleptic yttrium precursor, such as a precursor comprising an alkyl-substituted cyclopentadienyl ligand and an alkyl acetamitinate ligand such as bis-isopropylcyclopentadienyl-di-isopropylacetamidinate-yttrium, i.e. Y(EtCp)₂(iPr-amd).

In some embodiments, the reactant is selected from the list consisting of H₂O, H₂O₂, O₂, O₃, oxygen radicals, and oxygen ions.

In some embodiments, the threshold voltage shifting layer comprises lanthanum, the precursor comprises a lanthanum precursor, and the reactant comprises a boron reactant.

In some embodiments, the lanthanum precursor comprises one or more cyclopentadienyl ligands or alkyl substituted variants thereof.

In some embodiments, the lanthanum precursor comprises a lanthanum amidinate.

In some embodiments, the reactant comprises a sulfur reactant, and the sulfur reactant is selected from elemental sulfur, H₂S, an alkane thiol, an alkyl sulfide, and a dialkyl disulfide.

In some embodiments, the reactant comprises a boron reactant, and the boron reactant is selected from the list consisting of hydroboranes; alkylboranes; haloboranes; and amines, ethers, alcohols, thiols, and dialkyl sulfides thereof.

In some embodiments, the boron reactant is selected from diborane and borazine.

In some embodiments, the lanthanum precursor comprises Tris(isopropyl-cyclopentadienyl)lanthanum.

Further described herein is a method for depositing a layer for controlling a threshold voltage of a metal-oxide-semiconductor field effect transistor (MOSFET). The method comprises the steps of: providing a substrate within a reactor chamber. The substrate comprises a surface. The surface comprises a silicon oxide surface and/or a high-k dielectric surface. The method further comprises depositing a sulfide layer onto the silicon oxide surface and/or on the high-k dielectric surface by means of a cyclical deposition process. The cyclical deposition process comprises one or more cycles. Each cycle comprises: providing a precursor to the reaction chamber in a precursor pulse; providing a sulfur reactant to the reaction chamber in a sulfur reactant pulse; and, exposing the sulfide layer to a boron reactant, thereby converting the sulfide layer to a boride layer. Thus, a threshold voltage shifting layer is formed.

In some embodiments, the sulfide layer comprises a lanthanide or a transition metal, the precursor comprises a lanthanide precursor or a transition metal precursor, and the threshold voltage shifting layer comprises a lanthanum boride or a transition metal boride.

In some embodiments, the sulfide layer comprises an element selected from erbium, lanthanum, gadolinium, magnesium, cerium, titanium, tantalum, niobium, manganese, iron, nickel, vanadium, and cobalt; the precursor comprises a precursor selected from the list consisting of a lanthanum precursor, an erbium precursor, a gadolinium precursor, a cerium precursor, a titanium precursor, a tantalum precursor, a niobium precursor, a manganese precursor, an iron precursor, a nickel precursor, a vanadium precursor, and a cobalt precursor; and, the threshold voltage shifting layer comprises a boride selected from the list consisting of lanthanum boride, erbium boride, gadolinium boride, cerium boride, titanium boride, tantalum boride, niobium boride, manganese boride, iron boride, nickel boride, vanadium boride, and cobalt boride.

In some embodiments, the sulfide layer comprises lanthanum, the precursor comprises a lanthanum precursor, and the threshold voltage shifting layer comprises lanthanum boride.

In some embodiments, the lanthanum precursor comprises tris(isopropyl-cyclopentadienyl)lanthanum.

In some embodiments, the sulfur reactant is selected from the list consisting of elemental sulfur, H₂S, alkane thiols, alkyl sulfides, and dialkyl disulfides.

In some embodiments, the boron reactant is selected from the list consisting of diborane; hydroboranes; alkylboranes; haloboranes; and amines, ethers, alcohols, thiols, and dialkyl sulfides thereof.

In some embodiments, the boron reactant is selected from diborane and borazine.

In some embodiments, the threshold voltage shifting layer is grown at a growth rate of 0.1 nm per cycle or less during the one or more cycles.

In some embodiments, the threshold voltage shifting layer has a carbon content of less than 25 atomic percent.

In some embodiments, the threshold voltage shifting layer is deposited at a temperature of at least 100° C. to at most 400° C., or at a temperature of at least 150° C. to at most 350° C., or at a temperature of at least 200° C. to at most 300° C.

In some embodiments, the threshold voltage shifting layer is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

In some embodiments, the threshold voltage shifting layer has a thickness from at least 0.03 nm to at most 1.0 nm.

In some embodiments, the threshold voltage shifting layer is suitable for controlling a threshold voltage of a metal-oxide-semiconductor field effect transistor (MOSFET).

In some embodiments, the MOSFET comprises a gate all around structure.

In some embodiments, the gate all around structure includes a semiconductor material covered with a silicon oxide layer, and the threshold voltage shifting layer is deposited on the silicon oxide layer.

In some embodiments, the gate all around structure includes a semiconductor material covered with a silicon oxide layer, the silicon oxide layer is in direct contact with a high-k dielectric layer, and the threshold voltage shifting layer is deposited on the high-k dielectric

In some embodiments, the threshold voltage shifting layer is deposited in a cross-flow reactor.

In some embodiments, the threshold voltage shifting layer is deposited in a showerhead reactor.

In some embodiments, the threshold voltage shifting layer is deposited in a hot-wall reactor.

In some embodiments, and after the cyclical deposition process, the substrate is subjected to an anneal in an ambient comprising hydrogen and nitrogen, at a temperature from at least 300° C. to at most 600° C.

In some embodiments, the precursor is provided to the reactor chamber from a temperature-controlled precursor vessel.

In some embodiments, the temperature controlled precursor vessel is maintained at a temperature of at least 20° C. to at most 250° C., or at a temperature of at least 100° C. to at most 200° C.

In some embodiments, the precursor is provided to the reactor chamber by means of a carrier gas.

In some embodiments, the carrier gas is nitrogen or a noble gas.

In some embodiments, the precursor pulses last from at least 0.1 s to at most 20 s, and the reactant pulses last from at least 0.1 s to at most 20 s.

In some embodiments, the precursor pulse and the reactant pulse are separated by an intra-cycle purge.

In some embodiments, subsequent cycles are separated by an inter-cycle purge.

In some embodiments, the cyclical deposition process comprises a cyclical chemical vapor deposition process.

In some embodiments, the cyclical deposition process comprises an atomic layer deposition process.

In some embodiments, the cyclical deposition process comprises a thermal process.

In some embodiments, the method further comprises a step of depositing a further high-k dielectric layer on the threshold voltage shifting layer.

In some embodiments, the further high-k dielectric layer comprises hafnium oxide.

In some embodiments, the method further comprises a step of depositing a conductive layer on the further high-k dielectric layer.

In some embodiments, the conductive layer comprises a nitride.

In some embodiments, the conductive layer comprises silicon nitride.

In some embodiments, the conductive layer comprises a metal.

Further described is a structure comprising a threshold voltage shifting layer formed by means of a method as disclosed herein.

In some embodiments, the structure comprises a high-k dielectric layer between the threshold voltage shifting layer and a substrate.

In some embodiments, the threshold voltage shifting layer is positioned between a high-k dielectric layer and a substrate.

In some embodiments, the substrate comprises a SiO₂ surface, and the structure comprises the following sequence of layers, in the order given: SiO₂, threshold voltage shifting layer, high-k dielectric, electrode.

In some embodiments, the threshold voltage shifting layer comprises scandium oxide.

In some embodiment, the high-k dielectric layer comprises hafnium oxide.

In some embodiments, a thickness of the threshold voltage shifting layer is from at least 0.03 nm to at most 1.0 nm.

Further described is a metal oxide semiconductor field effect transistor comprising a structure as described herein.

Further described is a system. The system comprises one or more reaction chambers; a precursor gas source comprising a precursor; a reactant gas source comprising a reactant; an exhaust source; and, a controller. The controller is configured to control gas flow into at least one of the one or more reaction chambers to carry out a method as described herein.

Further described is an electrode comprising a stack of layers, in the following order: a first metal carbide layer, metal sulfide layer, and a second metal carbide layer.

In some embodiments, at least one of the first metal carbide layer and the second metal carbide layer comprise titanium carbide.

In some embodiments, the metal sulfide is selected from the list consisting of scandium sulfide, yttrium sulfide, and a lanthanide sulfide.

In some embodiments, the metal sulfide comprises cerium sulfide.

In accordance with yet further exemplary embodiments of the disclosure, a structure is formed using a method as described herein. The structure can include a substrate and a threshold voltage shifting layer formed overlying a surface of the substrate. Exemplary structures can further include one or more additional layers, such as an additional metal or conducting layer overlying the threshold voltage shifting layers and/or one or more insulating or dielectric layers underneath the threshold voltage shifting layers. The structure can be or form part of a CMOS structure, such as one or more of a PMOS and NMOS structure, or other device structure.

In accordance with yet additional embodiments of the disclosure, a device or portion thereof can be formed using a method and/or a structure as described herein. The device can include a substrate, an insulating or dielectric layer, a threshold voltage shifting layer overlying the insulating or dielectric layer, and optionally an additional metal layer overlying the threshold voltage shifting layer. The device can be or form part of, for example, a CMOS device.

In accordance with yet additional embodiments of the disclosure, a device or portion thereof can be formed using a method and/or a structure as described herein. The device can include a substrate, an interfacial layer such as a silicon oxide layer, a threshold voltage shifting layer overlying the interfacial layer, a high-k dielectric layer overlying the threshold voltage shifting layer, and optionally an additional metal layer overlying the threshold voltage shifting layer. The device can be or form part of, for example, a CMOS device.

In accordance with yet additional examples of the disclosure, a system to perform a method as described herein and/or to form a structure, device, or portion of either, is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2-4 illustrate exemplary structures in accordance with embodiments of the disclosure.

FIG. 5 illustrates a reactor system in accordance with additional exemplary embodiments of the disclosure.

FIGS. 6 and 7 show experimental results obtained on Metal-Oxide-Semiconductor capacitors (MOSCAPS) on a silicon substrate comprising a scandium oxide layer.

FIGS. 8 and 9 illustrate a method in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures, such as gate dielectrics or portions thereof for field effect transistors. Exemplary methods can be used to, for example, form CMOS devices, or portions of such devices. However, unless noted otherwise, the invention is not necessarily limited to such examples.

The term “threshold voltage shifting layer” as used herein refers to a layer which is useful for controlling the threshold voltage of a metal oxide field effect transistor. It may be equivalent to similar terms such as “threshold voltage tuning layer”, “dipole layer”, or “threshold voltage controlling layer”. The term “threshold voltage shifting layer” as used herein may be simply referred to as “layer”.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

As used herein, the term “gate all around transistor” may refer to devices which include a conductive material wrapped around a semiconductor channel region. As used herein, the term “gate all around transistor” may also refer to a variety of device architectures such as nanosheet devices, forksheet devices, vertical field effect transistors, stacked device architectures, etc.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber. Note that, as used herein, ALD processes are not necessarily comprised of a sequence of self-limiting surface reactions.

The term “threshold voltage” as used herein refers to a minimum gate voltage required to create a conductive path between the source and drain terminals of a field effect transistor.

The term “threshold voltage shifting layer” refers to a layer which can be used in the gate stack of a field effect transistor, and which can change the threshold voltage of that field effect transistor. When used herein, the term “threshold voltage shifting layer” may be equivalent to like terms such as threshold voltage adjusting layer, work function adjusting layer, work function shifting layer, flatband voltage adjusting layer, flatband voltage shifting layer, or simply “layer”.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The following abbreviations are used herein: Me stands for methyl; Et stands for ethyl; iPr stands for isopropyl; nPr stands for n-propyl; nBu stands for n-butyl; Cp stands for cyclopentadienyl; acac stands for acetylacetonate; fmd stands for formamidinate; hfac stands for hexafluoroacetylacetonate; N^{R,R′}R″-amd″ or N^{R}R″-amd when R=R′ refers to the amidinate ligand [R—N—C(R″)=N—R′], wherein R, R′ and R″ are C1-C5 hydrocarbyls, e.g. C1-C5 hydrocarbyls; R₂-amd″ stands for an amidinate ligand in which R═R′ and R″=H; thd stands for 2,2,6,6-tetramethylheptane-3,5-dionate; phen stands for phenanthroline.

The presently described methods and devices are useful for controlling the threshold voltage of field effect transistors. In some embodiments, the present methods and devices are particularly useful for controlling the threshold voltage of n-channel field effect transistors, such as n-channel metal-oxide semiconductor field effect transistors, such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, such as p-channel gate-all-around metal oxide semiconductor field effect transistors. In particular, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices are particularly useful for decreasing the gate voltage at which a conductive channel is produced between the source and drain of a p-MOSFET. The p-MOSFET may, for example, be comprised in a CMOS-based integrated circuit. In other words, the present methods and devices are particularly useful for increasing the voltage at which an n-MOSFET switches from an off-state to an on-state, and for decreasing the voltage at which a p-MOSFET switches from an off-state to an on-state. Similarly, the present methods and devices are particularly useful for increasing the flat band voltage of n-MOSFETS, and for decreasing the flat band voltage of p-MOSFETS. The presently methods and devices are particularly useful for the manufacture of n-MOSFETS and p-MOSFETS with a gate-all-around architecture. Additionally or alternatively, the present methods and devices may be of particular use in the context of systems-on-a-chip. Advantageously, the presently disclosed methods allow depositing threshold shifting layers contributing only minimally to the equivalent oxide thickness of the gate dielectric stack while simultaneously offering a low growth rate and providing a significant positive threshold voltage shift. Advantageously, the presently disclosed methods allow depositing threshold shifting layers having a low impurity content.

Described herein are methods for depositing a layer. The layer can be used, for example, for controlling a threshold voltage of a transistor, e.g. a MOSFET device such as a transistor comprising a semiconducting channel surrounded by a metal gate, such as a gate-all-around transistor. Accordingly, the layer is referred to as a threshold voltage shifting layer. The method comprises a step of providing a substrate within a reactor chamber. A suitable substrate includes a monocrystalline silicon wafer, e.g. a p-type monocrystalline silicon wafer. The substrate comprises a surface. The surface comprises a dielectric surface. The dielectric surface can comprise a silicon oxide surface. Additionally or alternatively, the dielectric surface can comprise a high-k surface. A threshold voltage shifting layer is then deposited onto the dielectric surface by means of a cyclical deposition process. In some embodiments, the threshold voltage shifting layer comprises an element selected from a lanthanide, yttrium, and scandium. The cyclical deposition process comprises one or more cycles. A cycle comprises, in the following order, a step of providing a precursor to the reaction chamber in a precursor pulse, and providing a reactant to the reaction chamber in a reactant pulse. Thus, a threshold voltage shifting layer is formed on the substrate.

In some embodiments, the threshold voltage shifting layer comprises scandium and the precursor comprises a scandium precursor. Such layers can have a low carbon impurity content, e.g. a carbon content of 5.0, 1.0, or 0.1 atomic percent, or less. In addition, such layers can be stable in air, have a high dielectric constant, have proper band alignment with silicon, are thermally stable, and offer good interface quality.

In some embodiments, the scandium precursor comprises a cyclopentadienyl-containing ligand.

In some embodiments, the scandium precursor is selected from the list consisting of ScCp₃, Sc(thd)₃, and Sc(iPr-amd)₃. Such precursors can advantageously offer a low ligand dissociation energy, and good thermodynamic stability. In some embodiments, the scandium precursor comprises a cyclopentadienyl ligand and an amidinate ligand. In some embodiments, the scandium-containing precursor has the formula: Sc(RCp)ₘ(R—N—C(R)═N—R)ₙ, wherein each R is independently selected from H and C1-C5 hydrocarbyl, wherein n and m range from at least 1 to at most 2, and wherein n+m equals 3 or 4. Exemplary scandium precursors are described in US20160315168 and include Sc(Cp)₂ (N^{iPr}Me-amd), Sc(EtCp)₂ (N^{iPr}Me-amd), and Sc(iPrCp)₂ (N^{iPr}Me-amd). Such precursors can advantageously offer a low ligand dissociation energy, and good thermodynamic stability. Such precursors can be particularly useful for forming scandium oxide layers in combination with an oxygen reactant, in which case a growth per cycle of less than 0.1 nm per cycle, e.g. of 0.05 nm per cycle may be obtained, thus providing excellent thickness control. In particular, when a precursor comprising two alkyl-substituted cyclopentadienyl ligands and an amidinate ligand such as Sc(iPrCp)₂ (N^{iPr} Me-amd) is used, excellent within wafer uniformity of smaller than 1% 1σ can be obtained together with a low carbon concentration of less than 1.0 atomic percent. This can result in reduced gate leakage current when this layer is used in a MOSFET. Additionally, a thusly grown scandium oxide layer can have minor effect on equivalent oxide thickness.

In some embodiments, the threshold voltage shifting layer comprises a scandium chalcogenide, and the reactant comprises a chalcogenide.

In some embodiments, the threshold voltage shifting layer comprises scandium oxide, and the reactant comprises an oxygen reactant selected from the list consisting of oxygen, ozone, hydrogen peroxide, and water. One advantageous oxygen reactant for use with a scandium precursor is water, which can lead to a threshold voltage shift of 300 mV for less than 0.5 nm thickness, and low gate leakage current.

In some embodiments, the cyclical deposition process has a growth rate per cycle of 0.05 nm per cycle or less, or of at least 0.01 nm per cycle to at most 0.03 nm per cycle, or of at least 0.03 nm per cycle to at most 0.05 nm per cycle, or of at least 0.05 nm per cycle to at most 0.1 nm per cycle. Such a scandium oxide layer, e.g. having a thickness of from at least 0.1 nm to at most 0.5 nm, can be advantageously used in advanced CMOS devices. The scandium oxide layer can be suitably used as a dipole layer positioned between an interfacial layer such as a silicon oxide layer and a high-k layer such as a hafnium oxide layer. For example, using Sc(iPrCp)₂(iPr-amd) as a scandium precursor, it was found that a 0.3 nm ScO can shift the flatband voltage (Vfb) of a metal-oxide-semiconductor capacitor (MOSCAP) by −230 mV without any equivalent oxide thickness (EOT) or gate leakage penalty when a scandium oxide layer is used in a MOSCAP between a silicon oxide layer and a hafnium oxide layer in the following stack: p-type monocrystalline silicon substrate, silicon oxide interfacial layer, scandium oxide threshold voltage shifting layer, hafnium oxide high-k layer, titanium nitride layer.

In some embodiments, the scandium precursor comprises ScCp₃, and the oxygen reactant comprises H₂O.

In some embodiments, the scandium precursor comprises Sc(thd)₃ and the oxygen reactant comprises O₃.

In some embodiments, the scandium precursor comprises Sc(thd)₃ and the oxygen reactant comprises a mixture of O₃ and H₂O. For example, the oxygen reactant comprises from at least 1.0 to at most 99 atomic percent O₃, or from at least 10 to at most 90 atomic percent O₃, or from at least 30 to at most 70 atomic percent O₃. For example, the oxygen reactant comprises from at least 1.0 to at most 99 atomic percent H₂O, or from at least 10 to at most 90 atomic percent H₂O, or from at least 30 to at most 70 atomic percent H₂O.

In some embodiments, the scandium precursor comprises Sc(iPrAMD)₃ and the oxygen reactant comprises H₂O.

In some embodiments, the scandium precursor comprises Sc(emd)₃ and the oxygen reactant comprises O₂.

In an exemplary embodiment, the scandium precursor is selected from a cyclopentadienyl-containing precursor such as Sc(Cp)₃. Optionally, the scandium precursor comprises a substituted or unsubstituted cyclopentadienyl ligand and one or more further ligands such amidinate ligands. An exemplary precursor comprising both alkyl-substituted cyclopentadienyl ligands and an amidinate ligand is Sc(iPrCp)₂ (N^{iPr} Me-amd). In some embodiments, the scandium precursor is selected from Sc(Cp)₃, Sc(EtCp)₃, Sc(MeCp)₃, Sc(nPrCp)₃, Sc(nBuCp)3, and Sc(iPrCp)₃.

A suitable oxidizing reagent includes an oxygen-containing gas or gas mixture, such as a gas comprising at least one of O₂, O₃, H₂O, and H₂O₂. The scandium oxide threshold voltage shifting layer may, for example, be deposited at a temperature of at least 200° C. to at most 300° C. A suitable substrate includes a silicon wafer such as a 300 mm p-type Si (100) wafer. The threshold voltage shifting layer can be deposited on an interfacial silicon oxide layer that in turn lies on a silicon substrate. Further layers can then be deposited to arrive at a structure comprising, in the following order, the substrate, the interfacial silicon oxide layer, the threshold voltage shifting layer, a high-k dielectric, and a conductive layer.

In an exemplary embodiment, Sc(iPrCp)₂ (N^{iPr} Me-amd) was used as a scandium precursor and H₂O was used as an oxygen reactant. In such a process, a growth rate per cycle of 0.046 nm/cycle was found at 225° C. was found with within-wafer non-uniformity of only 1%. The carbon content of the resulting scandium oxide layer was less than 1 atomic percent. A metal-oxide-semiconductor capacitor (MOSCAP) comprising, in the following order, a p-type silicon substrate, a silicon oxide interfacial layer, the scandium oxide layer, a hafnium oxide high-k dielectric, and silicon nitride, yielded a gate leakage current of only 1.0×10⁻⁸ A/cm². The effective dielectric constant of the resulting gate dielectric was 12.8.

In some embodiments, the threshold voltage shifting layer comprises scandium sulfide, and the reactant comprises a sulfur reactant. The sulfur reactant can, in some embodiments, be selected from the list consisting elemental sulfur, H₂S, an alkane thiol, an alkyl sulfide, and a dialkyl disulfide.

In some embodiments, the threshold voltage shifting layer comprises scandium selenide, and the reactant comprises a selenium reactant.

In some embodiments, the threshold voltage shifting layer comprises scandium telluride, and the reactant comprises a tellurium reactant.

In some embodiments, a scandium sulfide or a scandium telluride threshold voltage shifting layer is deposited on an interfacial silicon oxide on a substrate.

In some embodiments, a scandium sulfide or a scandium telluride threshold voltage shifting layer is deposited on a high-k dielectric overlying an interfacial silicon oxide layer that turn overlies a substrate.

In some embodiments, the scandium sulfide or scandium telluride threshold voltage shifting layer is deposited at a growth rate per cycle of 0.1 nm or less.

In some embodiments, the layer comprises scandium boride, and the reactant is a boron reactant. The use of a boron reactant can, in some embodiments, be used to scavenge underlying oxides, thereby minimizing the equivalent oxide thickness of a dielectric structure in which such a threshold voltage shifting layer is used.

In some embodiments, the boron reactant comprises a reducing agent. In some embodiments, the boron reactant comprises borazine.

In some embodiments, a scandium boride-containing threshold voltage shifting layer is deposited at a growth rate of 0.1 nm per cycle or less.

In some embodiments, the threshold voltage shifting layer comprises cerium, and the precursor comprises a cerium precursor. Exemplary cerium precursors include cerium diketonates such as cerium beta diketonates, cerium amidinates, cerium cyclopentadienyls, cerium alkoxides, and cerium alkylsilylamines.

In some embodiments, the cerium-containing threshold voltage shifting layer is grown at a growth rate per cycle of 0.05 nm per cycle or less, or of at least 0.01 nm per cycle to at most 0.03 nm per cycle, or of at least 0.03 nm per cycle to at most 0.05 nm per cycle, or of at least 0.05 nm per cycle to at most 0.1 nm per cycle. Such a cerium-containing threshold voltage shifting layer, e.g. having a thickness of from at least 0.1 nm to at most 0.5 nm, can be advantageously used in advanced CMOS devices.

In some embodiments, the cerium precursor comprises a cerium diketonate. In some embodiments, the cerium precursor is selected from the list consisting of: Ce(acac)₄, Ce(hfac)₄, Ce(thd)₄, and Ce(thd)₃phen.

In some embodiments, the cerium precursor comprises a cerium amidinate. In some embodiments, the cerium precursor comprises a compound selected from Ce(iPr₂-amd)₃ and Ce(iPrCp)₂(iPr₂-amd).

In some embodiments, the cerium precursor comprises a substituted or unsubstituted cyclopentadienyl ligand. In some embodiments, the cerium precursor comprises a compound selected from the list consisting of Ce(Cp)₃, Ce(EtCp)₃, Ce(iPrCp)₃, Ce(MeCp)₃, Ce(nPrCp)₃, and Ce(nBuCp)₃.

In some embodiments, the cerium precursor comprises a cerium alkoxide. In some embodiments, the cerium precursor comprises Ce(OCMe₂CH₂OMe)₄.

In some embodiments, the cerium precursor comprises one or more cerium alkylsylilamines. An exemplary cerium alkylsilylamine includes Ce[N(SiMe₃)₂]₃.

In some embodiments, the threshold voltage shifting layer comprises a cerium chalcogenide, and the reactant is a chalcogenide reactant. It shall be understood that a chalcogenide reactant comprises a chalcogen.

In some embodiments, the threshold voltage shifting layer comprises cerium oxide, and the chalcogenide reactant is an oxygen reactant, i.e. a reactant comprising oxygen. Exemplary oxygen reactants include H₂O, O₃, H₂O₂, O₂, oxygen plasma, oxygen radicals, and oxygen ions.

In some embodiments, the cerium comprised in a cerium oxide-containing threshold voltage shifting layer has a +4 oxidation state. Such threshold voltage shifting layers can be particularly advantageously used between an interfacial silicon oxide layer and a high-k dielectric such as hafnium oxide. In exemplary embodiments, the cerium layer can be used in the following stack of layers: silicon substrate/interfacial silicon oxide layer/cerium oxide threshold voltage shifting layer/hafnium oxide-containing high-k layer/conductive layer. In some embodiments, an electrode as described herein can be used as a conductive layer.

In some embodiments, a cyclopentadienyl-containing cerium precursor such as a cyclopentadienyl or alklycyclopentadienyl-containing cerium precursor such as tris(i-propylcyclopentadienyl)cerium(III), Ce(iPrCp)₃, can be used as a precursor.

In some embodiments, the cerium chalcogenide comprises cerium sulfide, and the chalcogenide reactant comprises a sulfur reactant. Exemplary sulfur reactants include elemental sulfur, H₂S, alkane thiols, alkyl sulfides, and dialkyl disulfides.

In some embodiments, a cyclopentadienyl-containing cerium precursor such as a cyclopentadienyl or alkylcyclopentadienyl-containing cerium precursor such as tris(isopropylcyclopentadienyl)cerium(III), Ce(iPrCp)₃, can be used as a precursor for forming a cerium sulfide-containing threshold voltage shifting layer. In some embodiments, the cerium precursor is selected from Ce(Cp)₃, Ce(EtCp)₃, Ce(MeCp)₃, Ce(nPrCp)₃, Ce(nBuCp)₃. An exemplary sulfur reactant can, in some embodiments, include H₂S.

In some embodiments, the threshold voltage shifting layer comprises cerium boride, in which case the reactant comprises a boron reactant selected from the list consisting of hydroboranes; alkylboranes; haloboranes; and amines, ethers, alcohols, thiols, and dialkyl sulfides thereof.

In some embodiments, the boron reactant is selected from diborane and borazine.

In some embodiments, a cyclopentadienyl-containing cerium precursor such as a cyclopentadienyl or alklycyclopentadienyl-containing cerium precursor such as tris(i-propylcyclopentadienyl)cerium(III), Ce(iPrCp)₃, can be used as a precursor for forming a cerium sulfide-containing threshold voltage shifting layer. In some embodiments, the cerium precursor is selected from Ce(Cp)₃, Ce(EtCp)₃, Ce(MeCp)₃, Ce(nPrCp)₃, Ce(nBuCp)₃. An exemplary boron reactant can, in some embodiments, include B₂H₆.

In some embodiments, the threshold voltage shifting layer comprises yttrium, and the precursor comprises an yttrium precursor. An yttrium oxide containing threshold voltage shifting layer can be advantageously used formed on a silicon and oxygen containing material overlying a monocrystalline silicon substrate; or on a high-k material such as a hafnium and oxygen-containing high-k material. An yttrium and oxygen-containing threshold voltage shifting layer such as Y₂O₃ can potentially offer various benefits. Indeed, it is not hygroscopic, can be deposited with high purity/low C impurity content, and yttrium precursors can be readily available.

In some embodiments, an yttrium oxide-containing threshold voltage shifting layer is grown at a growth rate per cycle of 0.05 nm per cycle or less, or of at least 0.01 nm per cycle to at most 0.03 nm per cycle, or of at least 0.03 nm per cycle to at most 0.05 nm per cycle, or of at least 0.05 nm per cycle to at most 0.1 nm per cycle. Such an yttrium oxide-containing threshold voltage shifting layer, e.g. having a thickness of from at least 0.1 nm to at most 0.5 nm, can be advantageously used in advanced CMOS devices.

In some embodiments, the reactant comprises an oxygen reactant selected from the list consisting of H₂O, H₂O₂, O₂, O₃, oxygen radicals, and oxygen ions. Thus, a threshold voltage shifting layer containing yttrium oxide can be formed.

In some embodiments, an yttrium oxide threshold voltage shifting layer can be particularly advantageously used between an interfacial silicon oxide layer and a high-k dielectric such as hafnium oxide. In exemplary embodiments, an yttrium oxide-containing threshold voltage shifting layer can be used in a structure comprising the following stack of layers: silicon substrate/interfacial silicon oxide layer/yttrium oxide-containing threshold voltage shifting layer/hafnium oxide-containing high-k layer/conductive layer. In some embodiments, an electrode as described herein can be used as a conductive layer.

In some embodiments, an yttrium oxide-containing threshold voltage shifting layer can be used in a structure comprising the following stack of layers: silicon substrate/interfacial silicon oxide layer/hafnium oxide-containing high-k layer/yttrium oxide-containing threshold voltage shifting layer/conductive layer. In some embodiments, an electrode as described herein can be used as a conductive layer.

Yttrium oxide-containing layers were surprisingly found to be highly effective for use as threshold voltage shifting layers: they were found not to be hygroscopic, and can be deposited with a high purity and low carbon content.

In some embodiments, the yttrium precursor comprises an unsubstituted cyclopentadienyl ligand and/or or an alkyl-substituted cyclopentadienyl ligand such as Cp, MeCp, EtCp, and iPrCp. Thus, in some embodiments, the yttrium precursor can be selected from Y(Cp)₃, Y(MeCp)₃, Y(EtCp)₃, and Y(iPrCp)₃.

In some embodiments, the yttrium precursor is a heteroleptic precursor that comprises a cyclopentadienyl ligand and an amidinate ligand. The cyclopentadienyl ligand can be an unsubstituted cyclopentadienyl ligand or an alkyl-substituted cyclopentadienyl ligand, such as a methyl, ethyl, propyl, or butyl-substituted cyclopentadienyl ligand. Suitable heteroleptic yttrium precursor include Y(Cp)₂(iPr₂-amd), Y(MeCp)₂(iPr₂-amd), Y(EtCp)₂(iPr₂-amd), Y(iPrCp)₂(iPr₂-amd), Y(Cp)₂(iPr₂-fmd), Y(MeCp)₂(iPr₂-fmd), Y(EtCp)₂(iPr₂-fmd), Y(iPrCp)₂(iPr₂-fmd), Y(Cp)₂(tBu₂-amd), Y(MeCp)₂(tBu₂-amd), Y(EtCp)₂(tBu₂-amd), Y(iPrCp)₂(tBu₂-amd), Y(Cp)₂(tBu₂-fmd), Y(MeCp)₂(tBu₂-fmd), Y(EtCp)₂(tBu₂-fmd), and Y(iPrCp)₂(tBu₂-fmd).

In some embodiments, the yttrium precursor comprises a diketonate ligand, such as a beta diketonate ligand. Suitable precursor comprising a diketonate ligand include Y(acac)₃, Y(thd)₃, and Y(hfac)₃.

In some embodiments, the yttrium precursor comprises an amidinate ligand, e.g. an alkylamidinate ligand such as iPr-amd, tBu-amd, iPr-fmd, and tBu-fmd. In some embodiments, the yttrium precursor is a heteroleptic precursor. Such a heteroleptic precursor can comprise an unsubstituted or alkyl-substituted cyclopentadienyl ligand and an amidinate ligand. An exemplary yttrium precursor includes Y(EtCp)₂(iPr-amd). In some embodiments, the yttrium precursor is a homoleptic precursor, and comprise several, for example three, identical amidinate ligands. Examples of such precursors include Y(iPr-amd)₃, Y(tBu-amd)₃, Y(iPr-fmd)₃, and Y(tBu-fmd)₃.

In some embodiments, the yttrium precursor comprises an alkylaminoboranate ligand, such as an N, N-dimethylaminodiboranate ligand. Examples of such precursors include Y(H₃BNMe₂BH₃)₃.

In some embodiments, the yttrium precursor comprises an alkylsilylamine ligand, such as a trimethylsilylamine ligand. Examples of such precursors include Y[N(SiMe₃)₂]₃.

In some embodiments, such an yttrium precursor can be used together with an oxygen reactant such as H₂O or O₂. Advantageously, such precursors can be highly stable and can be used together with the oxygen reagents listed herein to yield homogeneous, smooth, and high purity yttrium oxide threshold voltage shifting layers, at a suitable growth rate. The layers are air stable and advantageously do not require a capping layer. Such an yttrium oxide threshold voltage shifting layer may be grown, for example, at a substrate temperature of at least 200° C. to at most 300° C., or at a substrate temperature of at least 220° C. to at most 280° C., or at a substrate temperature of about 250° C. Thus, a cyclical deposition process involving self-limiting deposition cycles of an yttrium oxide threshold voltage shifting layer can be carried out.

In some embodiments, the yttrium precursor can be stored in a heated yttrium precursor source, such as an yttrium precursor vessel. The yttrium precursor can, for example, be directed to the reaction chamber by means of heated gas lines, either as a precursor vapor as such, or by means of a carrier gas such as a noble gas or N₂. In some embodiments, the yttrium precursor source can be maintained at a temperature of at least 100° C. to at most 200° C., or at a temperature of at least 130° C. to at most 170° C., or at a temperature of at least 140° C. to at most 155° C.

In an exemplary embodiment, Y(EtCp)₂(iPr-amd) was used as an yttrium precursor, the yttrium precursor source was maintained at 140° C. Precursor and reactant pulses were lasted 10 seconds, and inter-cycle purges and intra-cycle purges were carried out for 15 seconds. During the purges, the reaction was purged by means of N₂. At substrate temperatures from at least 225° C. to at most 300° C., a growth rate of about 1.45 Å/cycle was obtained when H₂O was used as an oxygen reactant. When O₂ was used as an oxygen reactant, the growth rate per cycle was found to increase from ca. 0 Å/cycle at 225° C. to ca. 0.68 Å/cycle at 300° C. yttrium oxide threshold voltage shifting layers grown using either H₂O or O₂ as a co-reactant and that were deposited at a substrate temperature of 300° C. were studied with x-ray photoelectron spectroscopy (XPS) in an as-deposited state and as covered with an in-situ deposited 3 nm thick hafnium oxide capping layer. A carbon level (>20 at. %) was observed in yttrium oxide threshold voltage shifting layers grown using O₂ as an oxygen reagent both with and without capping layer. When H₂O was used as a co-reactant, an almost stoichiometric Y₂O₃ threshold voltage shifting layer was obtained having a low carbon content, determined at less than 1 atomic percent with a hafnium oxide capping layer and at 4.6 atomic percent without a hafnium oxide capping layer.

In some embodiments, the reaction chamber is maintained at a pressure of from at least 0.2 Torr to at most 760 Torr, or from at least 1 Torr to at most 100 Torr, or from at least 1 Torr to at most 10 Torr during growth of the yttrium oxide containing threshold voltage shifting layer.

In some embodiments, the threshold voltage shifting layer comprises lanthanum, the precursor comprises a lanthanum precursor, and the reactant comprises a boron reactant.

In some embodiments, the lanthanum precursor comprises one or more cyclopentadienyl ligands or alkyl substituted variants thereof.

In some embodiments, the lanthanum precursor comprises a lanthanum aminidate.

In some embodiments, the reactant comprises a sulfur reactant. In exemplary embodiments, the sulfur reactant is selected from elemental sulfur, H₂S, an alkane thiol, an alkyl sulfide, and a dialkyl disulfide.

In some embodiments, the lanthanum precursor comprises Tris(isopropyl-cyclopentadienyl)lanthanum. In some embodiments, the lanthanum precursor comprises a substituted or unsubstituted cyclopentadienyl ligand. In some embodiments, the lanthanum precursor is selected from La(Cp)₃, La(EtCp)₃, La(MeCp)₃, La(nPrCp)₃, and La(nBuCp)₃.

In some embodiments, the lanthanum precursor comprises one or more substituted or unsubstituted cyclopentadienyl ligand. Additionally or alternatively, the lanthanum precursor comprises one or more ligands selected from an alkylsilylamine, a diazadiene, and an amidinate.

In some embodiments, the sulfur reactant is selected from the list consisting of S₈, H₂S, RSH, RSR′, RSSR′, SCl₂, and S₂Cl₂, wherein R and R′ are independently selected from aryl and a linear, branched, or cyclic alkyl or alkenyl.

In some embodiments, the reactant comprises a boron reactant. Exemplary boron reactants include hydroboranes; alkylboranes; haloboranes; and amines, ethers, alcohols, thiols, and dialkyl sulfides thereof.

In some embodiments, the boron reactant is selected from diborane and borazine.

In some embodiments, the lanthanum precursor is La(iPrCp)₃ and the sulfur reactant is H₂S.

Further described herein are methods for depositing a layer for controlling a threshold voltage that comprise converting a sulfide layer to a boride layer to form a threshold voltage shifting layer. In some embodiments, such methods can be used for depositing a layer for controlling a threshold voltage of a metal-oxide-semiconductor field effect transistor (MOSFET). The method comprises providing a substrate within a reactor chamber. The substrate comprises a surface. The surface comprises a dielectric surface, e.g. a silicon oxide surface and/or a high-k dielectric surface. The method further comprises depositing a sulfide layer onto the silicon oxide surface and/or on the high-k dielectric surface by means of a cyclical deposition process. The cyclical process comprises one or more cycles. A cycle comprises providing a precursor to the reaction chamber in a precursor pulse. Then, a cycle comprises providing a sulfur reactant to the reaction chamber in a sulfur reactant pulse, thereby forming a sulfide layer. A cycle then comprises exposing the sulfide layer to a boron reactant. Thus, the sulfide layer is converted to a boride layer and a threshold voltage shifting layer is formed.

In some embodiments, the sulfide layer comprises a lanthanide or a transition metal, and the precursor comprises a lanthanide precursor or a transition metal precursor. In such embodiments, the threshold voltage shifting layer comprises a lanthanum boride or a transition metal boride.

In some embodiments, the sulfide layer comprises an element selected from erbium, lanthanum, gadolinium, cerium, titanium, tantalum, niobium, manganese, iron, nickel, vanadium, and cobalt, and the precursor comprises a precursor selected from the list consisting of a lanthanum precursor, an erbium precursor, a gadolinium precursor, a cerium precursor, a titanium precursor, a tantalum precursor, a niobium precursor, a manganese precursor, an iron precursor, a nickel precursor, a vanadium precursor, and a cobalt precursor. In such embodiments, the threshold voltage shifting layer comprises a boride selected from the list consisting of lanthanum boride, erbium boride, gadolinium boride, cerium boride, titanium boride, tantalum boride, niobium boride, manganese boride, iron boride, nickel boride, vanadium boride, and cobalt boride. In some embodiments, the sulfide layer comprises a rare earth metal (RE-M), and the precursor comprises a rare earth metal precursor selected from the list consisting of RE-M(Cp)₃, RE-M(iPrCp)₃, RE-M(EtCp)₃, RE-M(MeCp)₃, RE-M(nPrCp)₃, RE-M(nBuCp)₃. In some embodiments, the sulfide layer comprises titanium, and the precursor comprises a titanium halide such a titanium chloride, such as TiCl₄. In some embodiments, the sulfide layer comprises manganese, and the precursor comprises a manganese precursor, such as a manganese precursor having the general formula Mn(R¹—N═CH—CH═N—R²)₂, wherein R¹ and R² are alkyls. In some embodiments, R¹ and R² are equal. In some embodiments, R¹ and R² are tert-butyl. In some embodiments, the sulfide layer comprises magnesium, and the precursor comprises a magnesium precursor, such as a magnesium precursor having the general formula Mg(R¹—N═CH—CH═N—R²)₂, wherein R¹ and R² are alkyls. In some embodiments, R¹ and R² are equal. In some embodiments, R¹ and R² are tert-butyl. In some embodiments, the magnesium precursor comprises a substituted or unsubstituted cyclopentadienyl ligand, such as an alkyl-substituted cyclopentadienyl ligand. In some embodiments, the magnesium precursor comprises Mg(EtCp)₂. In some embodiments, the sulfide layer comprises vanadium, and the precursor comprises a vanadium halide such a vanadium chloride, such as VCl₄.

In some embodiments, the sulfide layer comprises lanthanum, in which case the precursor comprises a lanthanum precursor, and in which case the threshold voltage shifting layer comprises lanthanum boride.

In some embodiments, the lanthanum precursor comprises an alkyl-substituted cyclopentadienyl ligand. An example of such a precursor is tris(isopropyl-cyclopentadienyl)lanthanum.

In some embodiments, the sulfur reactant is selected from the list consisting of elemental sulfur, H₂S, alkane thiols, alkyl sulfides, and dialkyl disulfides. In some embodiments, the sulfur reactant comprises H₂S.

In some embodiments, the boron reactant is selected from the list consisting of hydroboranes; alkylboranes; haloboranes; and amines, ethers, alcohols, thiols, and dialkyl sulfides thereof. In some embodiments, the boron reactant comprises diborane. In some embodiments, the boron reactant is selected from diborane and borazine.

It shall be understood that the following embodiments can apply to any one of the methods disclosed herein, irrespective of the precursor and/or reactant that is used in such methods, unless a corresponding embodiment would render the method in question unworkable.

In some embodiments, the threshold voltage shifting layer is grown at a growth rate of 0.1 nm per cycle or less during the one or more cycles.

In some embodiments, the threshold voltage shifting layer has a carbon content of less than 10 atomic percent, or less than 5 atomic percent, or less than 2 atomic percent, or less than 1 atomic percent.

In some embodiments, the threshold voltage shifting layer is deposited at a temperature of at least 100° C. to at most 400° C., or at a temperature of at least 150° C. to at most 350° C., or at a temperature of at least 200° C. to at most 300° C.

In some embodiments, the threshold voltage shifting layer is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

In some embodiments, the threshold voltage shifting layer has a thickness from at least 0.03 nm to at most 1.0 nm. Indeed, the threshold voltage shifting layer may be relatively thin, e.g. can be less than 0.5 nm thick, or less than 0.4 nm thick, or can be less than 0.3 nm thick, or can be less than 0.2 nm thick, or can be less than 0.1 nm thick, which may be desirable for many applications, including work function and/or threshold voltage adjustment layers, e.g. in the gate stack of p- or n-channel MOSFETs.

In some embodiments, the threshold voltage shifting layer has a thickness from at least 0.1 nm to at most 0.3 nm. In some embodiments the threshold voltage shifting layer has a thickness less than 3.0 nm. In some embodiments the threshold voltage shifting layer has a thickness less than 2.0 nm. In some embodiments the threshold voltage shifting layer has a thickness less than 1.0 nm. In some embodiments the threshold voltage shifting layer has a thickness less than 0.5 nm. In some embodiments the threshold voltage shifting layer has a thickness less than 0.4 nm. In some embodiments the threshold voltage shifting layer has a thickness less than 0.3 nm. In some embodiments the threshold voltage shifting layer has a thickness less than 0.2 nm. In some embodiments the threshold voltage shifting layer has a thickness less than 0.1 nm.

In some embodiments, the layer is suitable for controlling a threshold voltage of a metal-oxide-semiconductor field effect transistor (MOSFET).

In some embodiments, the MOSFET comprises a gate all around structure.

In some embodiments, the gate all around structure includes a semiconductor material covered with a silicon oxide layer, in which case the threshold voltage shifting layer can be deposited on the silicon oxide layer. This can be particularly advantageous in space constrained MOSFET designs, such as Gate-All-Around Devices.

In some embodiments, the gate all around structure includes a semiconductor material covered with a silicon oxide layer. In such embodiments, the silicon oxide layer can in turn be covered with a high-k dielectric layer, and the threshold voltage shifting layer is deposited on the high-k dielectric

In some embodiments, the threshold voltage shifting layer is deposited in a cross-flow reactor.

In some embodiments, the threshold voltage shifting layer is deposited in a showerhead reactor.

In some embodiments, the threshold voltage shifting layer is deposited in a hot-wall reactor. Doing so can advantageously enhance uniformity and/or repeatability of threshold voltage shifting layer deposition processes.

In some embodiments, threshold voltage shifting layer can include impurities, such as halides, carbon, hydrogen or the like, for example in an amount of less than 25 atomic percent, less than 15 atomic percent, less than 5 atomic percent, one atomic percent, less than 0.2 atomic percent, or less than 0.1 atomic percent, or less than 0.05 atomic percent, alone or combined. In some embodiments, the carbon content of the threshold voltage shifting layer is less than 25 atomic percent, less than 15 atomic percent, or less than 5 atomic percent.

In some embodiments, the substrate is subjected to an annealing step after the cyclical deposition process has been carried out. The annealing step can be carried out, for example, in an ambient comprising hydrogen and nitrogen. The annealing step can be carried out, for example, at a temperature of at least 300° C. to at most 600° C., or at a temperature of at least 300° C. to at most 400° C., or at a temperature of at least 400° C. to at most 500° C., or at a temperature of at least 500° C. to at most 600° C. The anneal can be carried out for example, for from at least 5 minutes to at most 40 minutes, for example from at least 10 minutes to at most 30 minutes. In an exemplary embodiment, the annealing step is carried out at from at least 400° C. to at most 500° C., e.g. at 420° C., for from at least 10 minutes to at most 30 minutes, e.g. for 20 minutes, in forming gas, i.e. H₂ in N₂. In exemplary embodiments, the forming gas can comprise from at least 1 atomic percent to at most 20 atomic percent H₂ in N₂, for example about 5 atomic percent H₂ in N₂.

In some embodiments, the precursor is provided to the reactor chamber from a temperature-controlled precursor vessel. In some embodiments, the temperature-controlled precursor vessel is configured for cooling the precursor. In some embodiments, the temperature-controlled precursor vessel is configured for heating the precursor. In some embodiments, the temperature controlled precursor vessel is maintained at a temperature of at least −50° C. to at most 20° C., or at a temperature of at least 20° C. to at most 250° C., or at a temperature of at least 100° C. to at most 200° C.

In some embodiments, the precursor is provided to the reactor chamber by means of a carrier gas. Exemplary carrier gasses include nitrogen and a noble gas such as He, Ne, Ar, Xe, or Kr.

In some embodiments, the precursor pulses last from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s. In some embodiments, the reactant pulses last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

In some embodiments, the precursor pulse and the reactant pulse are separated by an intra-cycle purge.

In some embodiments, subsequent cycles are separated by an inter-cycle purge.

In some embodiments, the cyclical deposition process comprises a cyclical chemical vapor deposition process.

In some embodiments, the cyclical deposition process comprises an atomic layer deposition process.

In some embodiments, the cyclical deposition process comprises a thermal process.

In some embodiments, the method further comprises a step of depositing a further high-k dielectric layer on the threshold voltage shifting layer. In some embodiments, the further high-k dielectric layer comprises Hafnium oxide.

In some embodiments, the method further comprises a step of depositing a conductive layer on the further high-k dielectric layer. In some embodiments, the conductive layer comprises a nitride such as silicon nitride. In some embodiments, the conductive layer comprises a metal such as aluminum, copper, or cobalt.

Further described herein is a structure that comprises a threshold voltage shifting layer formed by means of a method as described herein. In some embodiments, the structure comprises a high-k dielectric layer between the threshold voltage shifting layer and a substrate.

In some embodiments, the threshold voltage shifting layer is positioned between a high-k dielectric layer and a substrate. In some embodiments, the substrate comprises a SiO₂ surface, and the structure comprises the following sequence of layers, in the order given: SiO₂, threshold voltage shifting layer, high-k dielectric, conductive layer. The conductive layer can, in some embodiments, comprise an electrode as described herein.

In some embodiments, the threshold voltage shifting layer comprises scandium oxide. Alternatively, another threshold voltage shifting layer disclosed herein can be used.

In some embodiments, the high-k dielectric layer comprises hafnium oxide.

In some embodiments, the structure comprises a high-k dielectric layer between the threshold voltage shifting layer and a substrate. In some embodiments the structure comprises the following sequence of layers, in the following order: silicon oxide/threshold shifting layer/hafnium oxide/titanium nitride. As an alternative to hafnium oxide, another high-k dielectric such as aluminum oxide or niobium oxide may be used as well. In this configuration, the threshold shifting layer may have a thickness of, for example, from 0.1 nm to 2.0 nm, e.g. a thickness of 0.2 nm to 1.0 nm, e.g. a thickness of about 0.5 nm, or 0.4 nm, or 0.3 nm, or less. Such configurations are particularly useful for increasing the threshold voltage in n-MOSFETS, or for decreasing the threshold voltage in p-MOSFETS.

In some embodiments, the structure comprises a threshold voltage shifting layer between a high k dielectric layer and a substrate. In some embodiments the structure comprises the following sequence of layers, in the following order: silicon-containing interfacial layer such as silicon oxide, high-k material such as hafnium oxide, threshold voltage shifting layer, conductive material such as titanium nitride. The silicon oxide layer may be an interfacial silicon oxide layer formed on a silicon substrate, e.g. as a chemical oxide. As an alternative to hafnium oxide, another high-k dielectric such as aluminum oxide or niobium oxide may be used as well. In this configuration, the threshold shifting layer may have a thickness of, for example, from 0.1 nm to 2.0 nm, e.g. a thickness of 0.2 nm to 1.0 nm, e.g. a thickness of about 0.5 nm. Such configurations are particularly useful for inducing a positive threshold voltage shift in n-MOSFETS. Alternatively, such configurations are particularly useful for inducing a negative threshold voltage shift in p-MOSFETS.

In some embodiments, a thickness of the threshold voltage shifting layer is from at least 0.03 nm to at most 1.0 nm.

Further described herein is a metal oxide semiconductor field effect transistor comprising a structure as described herein.

Further described herein is a system that comprises one or more reaction chambers. The system further comprises a precursor gas source comprising a precursor; a reactant gas source comprising a reactant; an exhaust source; and a controller. The controller is configured to control gas flow into at least one of the one or more reaction chambers to carry out a method as described herein.

Further described herein is an electrode comprising a stack of layers, in the following order: a first metal carbide layer, a metal sulfide layer, and a second metal carbide layer. In some embodiments, the electrode is comprised in a structure as described herein.

In some embodiments, at least one of the first metal carbide layer and the second metal carbide layer comprises titanium carbide.

In some embodiments, the metal sulfide is selected from the list consisting of scandium sulfide, yttrium sulfide, and a lanthanide sulfide.

In some embodiments, the metal sulfide comprises cerium sulfide. In some embodiments, the metal sulfide is grown according to a method as described herein.

In some embodiments, growing a cerium sulfide layer comprises employing a cyclical deposition process that comprises a step of providing a substrate within a reactor chamber, the substrate comprising a surface, the surface comprising a metal carbide surface, such as a titanium carbide surface. Using a cyclical deposition process, a cerium sulfide layer is deposited onto the metal carbide surface. The cyclical deposition process comprises one or more cycles. A cycle comprises providing a cerium precursor to the reaction chamber in a cerium precursor pulse; and providing a sulfur reactant to the reaction chamber in a sulfur reactant pulse. Thus, a cerium sulfide layer is formed on the substrate.

Exemplary cerium precursors include substituted or unsubstituted cyclopentadienyl-containing cerium precursors such as Ce(iPrCp)₃.

In some embodiments, the metal sulfide comprises yttrium sulfide. In some embodiments, the metal sulfide is grown according to a method as described herein.

In some embodiments, growing an yttrium sulfide layer comprises employing a cyclical deposition process that comprises a step of providing a substrate within a reactor chamber, the substrate comprising a surface, the surface comprising a metal carbide surface, such as a titanium carbide surface. Using a cyclical deposition process, an yttrium sulfide layer is deposited onto the metal carbide surface. The cyclical deposition process comprises one or more cycles. A cycle comprises providing an yttrium precursor to the reaction chamber in an yttrium precursor pulse; and providing a sulfur reactant to the reaction chamber in a sulfur reactant pulse. Thus, an yttrium sulfide layer is formed on the substrate. In some embodiments, a further metal carbide layer is then formed on the yttrium sulfide layer.

Suitable sulfur reactants include sulfur-containing gasses such as H₂S.

A stack comprising, in the order given, a metal carbide layer, a cerium sulfide layer, and a further metal carbide layer, e.g. a stack comprising, in the order given, titanium carbide, cerium sulfide, and titanium carbide can be used as a conductive layer in a gate stack of a MOS transistor, for example in an nMOS transistor comprised in a CMOS-based logic circuit.

Further described herein is an electrode comprising a stack of layers, in the following order: a first metal carbide layer, a metal boride layer, and a second metal carbide layer. In some embodiments, the electrode is comprised in a structure as described herein.

In some embodiments, at least one of the first metal carbide layer and the second metal carbide layer comprises titanium carbide.

In some embodiments, the metal boride is selected from the list consisting of scandium boride, yttrium boride, and a lanthanide boride.

In some embodiments, the metal boride comprises cerium boride. In some embodiments, the metal boride is grown according to a method as described herein.

In some embodiments, growing a cerium boride layer comprises employing a cyclical deposition process that comprises a step of providing a substrate within a reactor chamber, the substrate comprising a surface, the surface comprising a metal carbide surface, such as a titanium carbide surface. Using a cyclical deposition process, a cerium boride layer is deposited onto the metal carbide surface. The cyclical deposition process comprises one or more cycles. A cycle comprises providing a cerium precursor to the reaction chamber in a cerium precursor pulse; and providing a boron reactant to the reaction chamber in a boron reactant pulse. Thus, a cerium boride layer is formed on the substrate.

Exemplary cerium precursors include substituted or unsubstituted cyclopentadienyl-containing cerium precursors such as Ce(iPrCp)₃.

Suitable boron reactants include boron hydrides such as BH₃ and B₂H₆.

A stack comprising, in the order given, a metal carbide layer, a cerium boride layer, and a further metal carbide layer, e.g. a stack comprising, in the order given, titanium carbide, cerium boride, and titanium carbide can be used as a conductive layer in a gate stack of a MOS transistor, for example in an nMOS transistor comprised in a CMOS-based logic circuit.

In some embodiments, the metal boride comprises yttrium boride. In some embodiments, the metal boride is grown according to a method as described herein.

In some embodiments, growing an yttrium boride layer comprises employing a cyclical deposition process that comprises a step of providing a substrate within a reactor chamber, the substrate comprising a surface, the surface comprising a metal carbide surface, such as a titanium carbide surface. Using a cyclical deposition process, an yttrium boride layer is deposited onto the metal carbide surface. The cyclical deposition process comprises one or more cycles. A cycle comprises providing an yttrium precursor to the reaction chamber in an yttrium precursor pulse; and providing a boron reactant to the reaction chamber in a boron reactant pulse. Thus, a cerium boride layer is formed on the substrate.

Suitable yttrium precursors are described elsewhere herein.

Suitable boron reactants include boron hydrides such as BH₃ and B₂H₆.

A stack comprising, in the order given, a metal carbide layer, an yttrium boride layer, and a further metal carbide layer, e.g. a stack comprising, in the order given, titanium carbide, yttrium boride, and titanium carbide can be used as a conductive layer in a gate stack of a MOS transistor, for example in an nMOS transistor comprised in a CMOS-based logic circuit.

In some embodiments, the metal boride comprises a rare earth boride. In some embodiments, the rare earth boride is grown according to a method as described herein.

In some embodiments, growing a rare earth boride layer comprises employing a cyclical deposition process that comprises a step of providing a substrate within a reactor chamber, the substrate comprising a surface, the surface comprising a metal carbide surface, such as a titanium carbide surface. Using a cyclical deposition process, a rare earth boride layer is deposited onto the metal carbide surface. The cyclical deposition process comprises one or more cycles. A cycle comprises providing a rare earth metal precursor to the reaction chamber in a rare earth precursor pulse; and providing a boron reactant to the reaction chamber in a boron reactant pulse. Thus, a rare earth metal boride layer is formed on the substrate.

Suitable rare earth metal precursors are described elsewhere herein.

Suitable boron reactants include boron hydrides such as BH₃ and B₂H₆.

A stack comprising, in the order given, a metal carbide layer, an rare earth boride layer, and a further metal carbide layer, e.g. a stack comprising, in the order given, titanium carbide, a rare earth boride, and titanium carbide can be used as a conductive layer in a gate stack of a MOS transistor, for example in an nMOS transistor comprised in a CMOS-based logic circuit.

In some embodiments, a boride, such as a rare earth boride or a cerium boride or an yttrium boride, comprised in a stack comprising, in the order given, a metal carbide layer, a boride layer, and a further metal carbide layer, can be formed by means of a cyclical deposition process that comprises one or more super cycles. A super cycle comprises first forming a sulfide, and then exposing the sulfide layer to a boron reactant. Such cyclical deposition processes, and in particular how to form a sulfide layer and how to expose a sulfide layer to a boron reactant, are described in more detail elsewhere herein. An exemplary cyclical deposition process comprises forming a sulfide comprises executing one or more sulfide deposition cycles, a sulfide deposition cycle comprises executing a precursor pulse that comprises exposing a substrate to a precursor, and executing a sulfur reactant pulse that comprises exposing the substrate to a sulfur reactant. Exposing the sulfide layer to the boron reactant can result in conversion of the sulfide layer to a boride layer. Thus, a boride layer can be formed that can be employed in an electrode comprising a metal carbide layer, the boride layer, and another metal carbide layer.

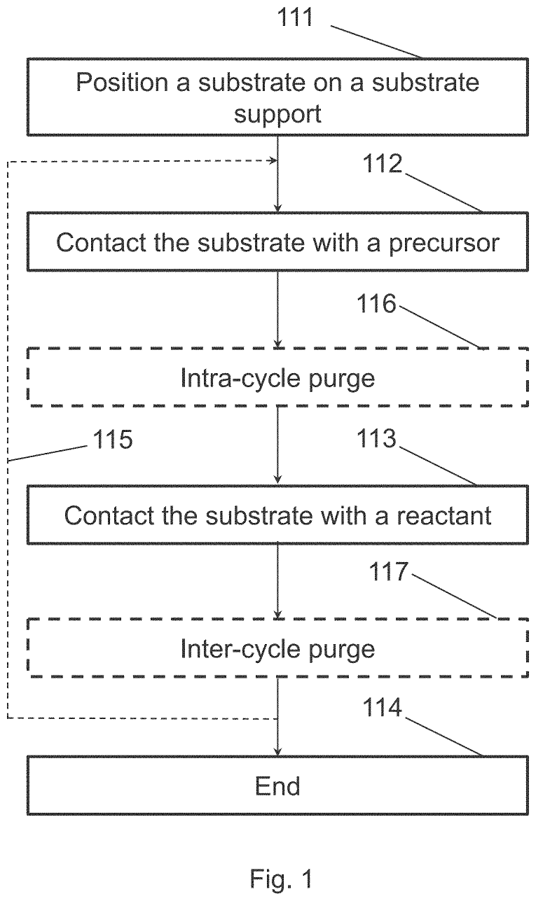

Turning now to the figures, FIG. 1 illustrates a method 100 in accordance with exemplary embodiments of the disclosure. Method 100 can be used to, for example, form a gate electrode structure suitable for NMOS, and/or CMOS devices, such as for uses as a threshold voltage shifting layer in a CMOS device. The present layers are particularly suitable for use as threshold voltage control layers in n-channel MOSFETs. However, unless otherwise noted, methods are not limited to such applications.

The method includes the steps of providing a substrate within a reaction chamber of a reactor (step 111). The reaction chamber can be or include a reaction chamber of a chemical vapor deposition reactor system configured to perform a cyclical deposition process. Additionally or alternatively, the reaction chamber can be or can include a reaction chamber of an atomic layer deposition reactor system configured to perform a cyclical deposition process. The reaction chamber can be a standalone reaction chamber or part of a cluster tool.

The method further includes using a cyclical deposition process, depositing a threshold voltage shifting layer as described herein, onto a surface of the substrate. The substrate comprises a silicon oxide surface and/or a high-k dielectric surface. Then, the method comprises cyclically executing one or more cycles (115), e.g. a plurality of cycles, e.g. 2, 5, 10, or 20, or more cycles. A cycle can comprise the following steps, in the following order: a step of contacting the substrate with a precursor (112), and a step of contacting the substrate with a reactant (113). Alternatively, a cycle can comprise the following steps, in the following order: a step of contacting the substrate with a reactant, and a step of contacting the substrate with a precursor. Thus, a threshold voltage shifting layer is deposited on the substrate, and the method ends.

Optionally, the step of contacting the substrate with the precursor and the step of contacting the substrate with the reactant can be separated by an intra-cycle purge (116). Additionally or alternatively, subsequent cycles can, in some embodiments, be separated by an inter-cycle purge (117).

The method can include cyclically repeating a plurality of deposition cycles (115). A deposition cycle comprises the step of contacting the substrate with a precursor (112), and the step of contacting the substrate with a reactant (113). Optionally, a deposition cycle comprises an intra-cycle purge (116) and/or an inter-cycle purge (117). The deposition cycle can be repeated one or more times, based on, for example, a desired thickness of the threshold voltage shifting layer. For example, if the thickness of the threshold voltage shifting layer is less than desired for a particular application, then the step of providing a precursor to the reaction chamber and providing a reactant to the reaction chamber can be repeated one or more times. Once the threshold voltage shifting layer has been deposited to a desired thickness, the substrate can be subjected to additional processes to form a device structure and/or device.

The method can include heating the substrate to a desired deposition temperature within the reaction chamber. In some embodiments of the disclosure, the method includes heating the substrate to a temperature of less than 500° C. For example, in some embodiments of the disclosure, heating the substrate to a deposition temperature may comprise heating the substrate to a temperature between approximately 20° C. and approximately 500° C., about 50° C. and about 400° C., about 100° C. and about 300° C., or about 150° C. and about 250° C.

In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

During the method, a threshold voltage shifting layer is deposited onto a surface of the substrate using a cyclical deposition process. The cyclical deposition process can include cyclical CVD, ALD, or a hybrid cyclical CVD/ALD process. Preferably, the cyclical deposition process employs reaction conditions which, when combined with a selected precursor—reactant pair, allow for self-limiting surface reactions to occur. For example, in some embodiments, the growth rate of a particular ALD process may be low compared with a CVD process.

Advantageously, the cyclical deposition process can be a thermal deposition process. In these cases, the cyclical deposition process does not include use of a plasma to form activated species for use in the cyclical deposition process. In the case of thermal cyclical deposition processes, a duration of the step of providing the precursor to the reaction chamber and/or a duration of the step of providing the precursor to the reaction chamber can be relatively long to allow the precursor, respectively reactant, to react with a surface of the substrate. For example, the duration can be greater than or equal to 5 seconds or greater than or equal to 10 seconds or between about 5 and 10 seconds.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process.

During at least one of the intra-cycle purge (116) and the inter-cycle purge (117), the reaction chamber can be purged using a vacuum and/or an inert gas to mitigate gas phase reactions between precursors and reactants and enable partly or fully self-saturating surface reactions—e.g., in the case of ALD. Additionally or alternatively, the substrate may be moved to separately contact a first vapor phase reactant, e.g. a precursor, and a second vapor phase reactant, e.g. an oxygen-containing gas. Additionally or alternatively, gaseous species may be removed from the reaction chamber during the intra-cycle purge (116) and/or the inter-cycle purge (117) by mean of a gas removal device such as a pump. Surplus chemicals and reaction byproducts, if any, can be removed from the substrate surface or reaction chamber, such as by purging the reaction space or by moving the substrate before the substrate is contacted with the next reactive chemical.

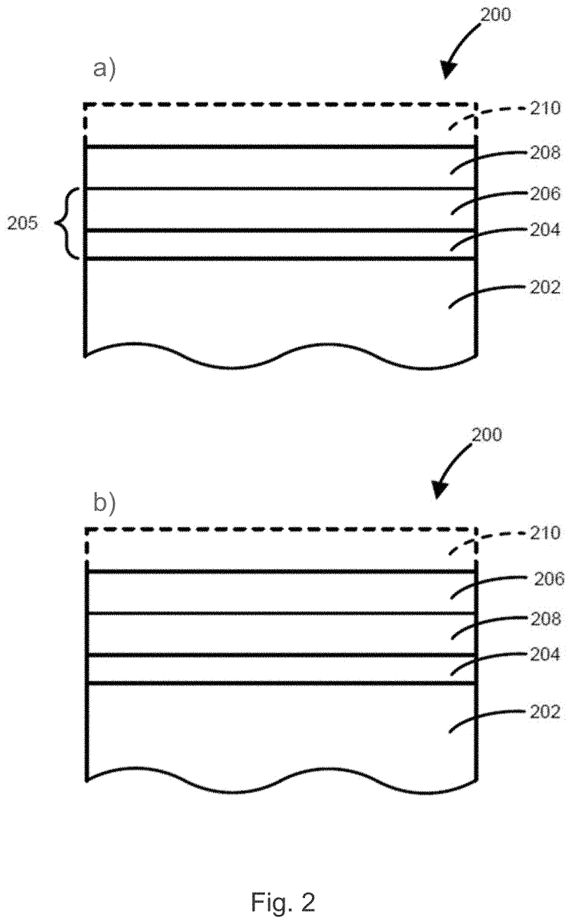

FIG. 2, panel a) illustrates a structure/a portion of a device (200) in accordance with additional examples of the disclosure. The device or structure (200) includes a substrate (202), dielectric or insulating material (205), and a threshold voltage shifting layer (208). In the illustrated example, the structure (200) also includes an additional conducting layer (210). The substrate (202) can be or include any of the substrate material described herein. The dielectric or insulating material (205) can include one or more dielectric or insulating material layers. By way of example, dielectric or insulating material (205) can include an interface layer (204) and a high-k material (206) deposited overlying interface layer (204). In some cases, the interface layer (204) may not exist or may not exist to an appreciable extent. The interface layer (204) can include an oxide, such as a silicon oxide, which can for example be formed on a, for example monocrystalline silicon, surface of the substrate (202) using, for example, a chemical oxidation process or an oxide deposition process. The high-k material (206) can be or include, for example, a metal oxide having a dielectric constant greater than about 7. In some embodiments, the high-k material has a dielectric constant higher than the dielectric constant of silicon oxide. Exemplary high-k materials include hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃) or lanthanum oxide (La₂O₃), mixtures thereof, and laminates thereof.

FIG. 2, panel b) illustrates another structure/a portion of a device 200 in accordance with additional examples of the disclosure. It is similar to the structure shown in FIG. 2, panel a), except that the threshold voltage shifting layer (208) is situated between the interface layer (204) and the high-k material (206).

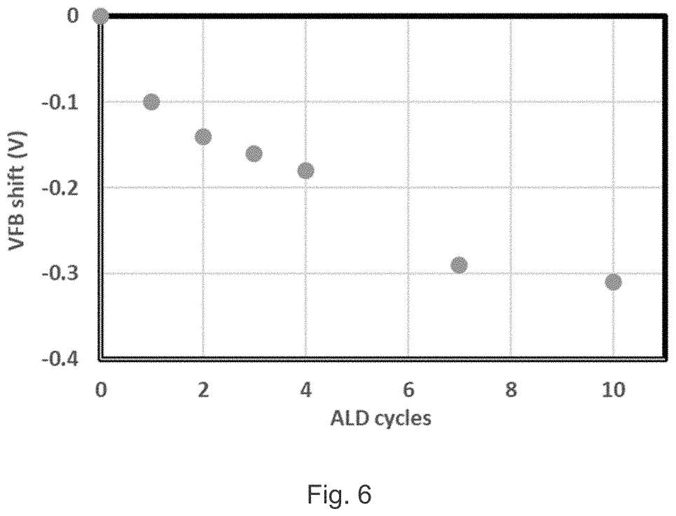

FIG. 6 shows experimental results obtained on metal-oxide-semiconductor capacitors (MOSCAP) using a structure as shown in FIG. 2, panel b). In particular, the following stack of layers was used: p-type silicon substrate, SiO₂ interface layer, scandium oxide dipole layer, Hafnium oxide as high-k material, and TiN as conductive material. The threshold voltage was deposited using an ALD process under conditions that facilitate self-limiting surface reactions. The maximum process temperature was below 450° C. The experimental results show that the threshold voltage shift can be tuned well from 0 (corresponding to no threshold voltage shifting layer) to 300 meV using scandium oxide as a threshold voltage shifting layer positioned between a silicon oxide interface layer and a hafnium oxide high-k material, even when using very thin threshold voltage shifting layers using 6 ALD cycles or less, which corresponds to a threshold voltage shifting layer thickness of less than 0.5 nm. Additionally, very small gate leakage currents were obtained.

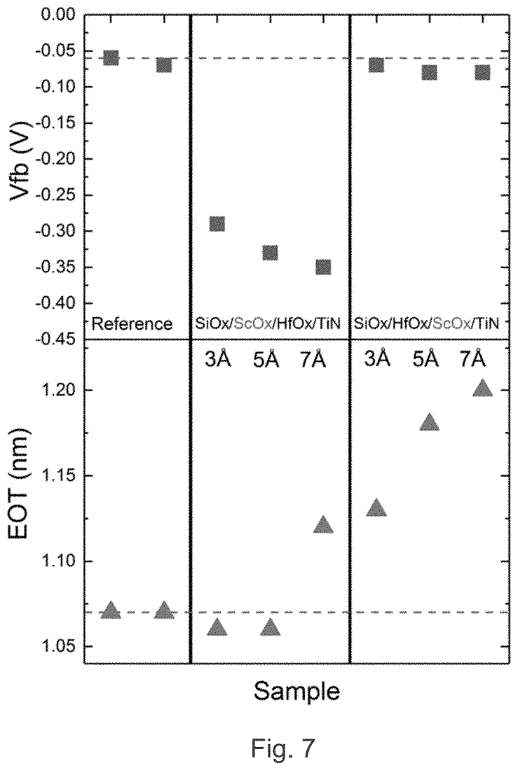

FIG. 7 shows further experimental results obtained on MOSCAPS on a silicon substrate comprising a scandium oxide layer. In particular, FIG. 7 compares the results obtained for a scandium oxide threshold voltage shifting layer positioned between a silicon oxide interfacial layer and a hafnium oxide high-k layer, and compares them to results obtained for a reference without threshold voltage shifting layer, and to results obtained for a scandium oxide threshold voltage shifting layer deposited on top of a high-k layer that in turn overlays a silicon oxide interface layer. The results indicate that a significant threshold voltage shift can be obtained for scandium oxide deposited on silicon oxide, without incurring an equivalent oxide thickness penalty, when the thickness of the threshold voltage shifting layer is kept below 0.5 nm. It shall be noted that no high temperature anneal is needed for obtaining these results. Though optionally, a forming gas anneal as described herein can be used.

The threshold voltage shifting layer (208) can be formed according to a method as described herein. Because the threshold voltage shifting layer (208) is formed using a cyclical deposition process and/or due to diffusion and/or mixing effects, the concentration of elements contained in the threshold voltage shifting layer (208) can vary from a bottom of the threshold voltage shifting layer (208) to a top of threshold voltage shifting layer (208) by, for example, controlling an amount of precursor and/or reactant and/or respective pulse times during one or more deposition cycles. In some cases, the threshold voltage shifting layer 208 can have a stoichiometric composition. In other embodiments, the threshold voltage shifting layer (208) can have a non-stoichiometric composition. An effective work function and other properties of a gate stack comprising the threshold voltage shifting layer (208) can be altered by altering the amount of the elements contained in the layer or in a deposition cycle.

An effective work function of a gate stack comprising a threshold voltage shifting layer 208 can from at least 4.0 eV to at most 5.1 eV. An effective work function of a gate stack can be shifted by about 10 meV to about 400 meV, or about 30 meV to about 300 meV, or about 50 meV to about 200 meV using a threshold voltage shifting layer as described herein.

A threshold voltage shifting layer (208) can form a continuous film—e.g., using method 100—at a thickness of less than <5 nm, <4 nm, <3 nm, <2 nm, <1.5 nm, <1.2 nm, <1.0 nm, or <0.9 nm. The threshold voltage shifting layer (208) can be relatively smooth, with relatively low grain boundary formation. In some cases, the threshold voltage shifting layer (208) may be at least partially amorphous. Advantageously, the threshold voltage shifting layer (208) can be entirely or substantially entirely amorphous. The RMS roughness of an exemplary threshold voltage shifting layer 208 can be <1.0 nm, <0.7 nm, <0.5 nm, <0.4 nm, <0.35 nm, or <0.3 nm, at a thickness of less than 10 nm. Alternatively, the threshold voltage shifting layer (208) may have an average thickness which is thinner than e.g. 1.0 nm, 0.5 nm, 0.3 nm, 0.2 nm, or 0.1 nm and be discontinuous. For example, the threshold voltage shifting layer may comprise isolated islands, gaps, and/or holes. The threshold voltage shifting layer (208) may even entirely consist of a plurality of isolated atoms and/or clusters of atoms.

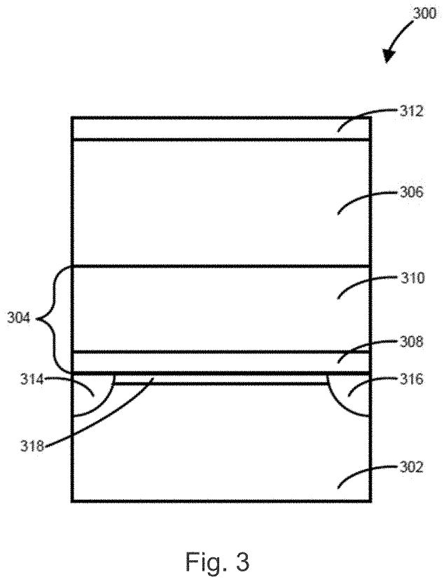

FIG. 3 illustrates another exemplary structure (300) in accordance with examples of the disclosure. The device or structure (300) includes a substrate (302), a dielectric or insulating material (304), and a threshold voltage shifting layer (306). The dielectric or insulating material (304) comprises an interfacial layer (308) and a high-k dielectric layer (310). A suitable interfacial layer includes silicon oxide. In the illustrated example, the structure (300) also includes an additional conducting layer (312). In the illustrated example, the threshold voltage shifting layer (306) is deposited on top of the high-k dielectric layer (310). Alternatively, the threshold voltage shifting layer (306) may be deposited on top of the interfacial layer (308), and the high-k dielectric layer (310) may be deposited on the threshold voltage shifting layer (306).

In the illustrated example, the substrate (302) includes a source region (314), a drain region (316), and a channel region (318). Although illustrated as a horizontal structure, structures and devices in accordance with examples of the disclosure can include vertical and/or three-dimensional structures and devices, such as FinFET devices, gate-all-around field effect transistors, and stacked device architectures.

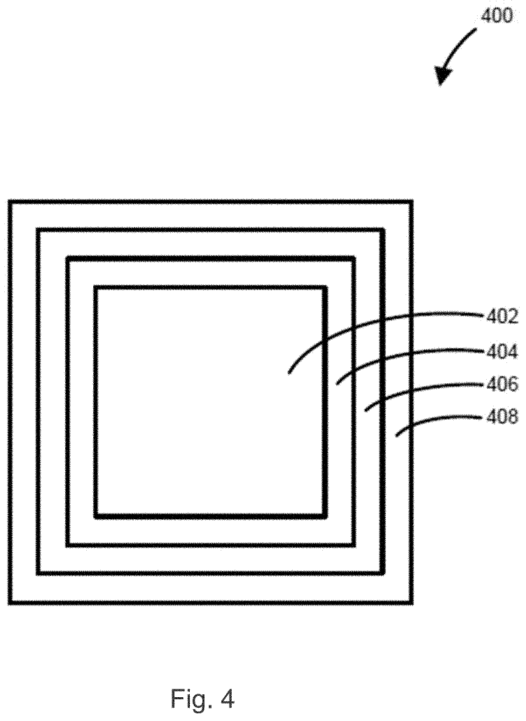

FIG. 4 illustrates another structure (400) in accordance with examples of the disclosure. This structure (400) is suitable for gate all around field effect transistors (GAA FET) (also referred to as lateral nanowire FET) devices and the like.

In the illustrated example, the structure (400) includes a semiconductor material (402), a dielectric material (404), a threshold shifting layer (406), and a conducting layer (408). The dielectric material suitably comprises an interfacial layer, e.g. silicon oxide, and a high-k dielectric layer, analogous to the layer sequences illustrated in FIGS. 2 and 3. The structure (400) can be formed overlying a substrate, including any substrate materials described herein.

In the illustrated example, the threshold voltage shifting layer (406) is deposited on top of the dielectric layer. Alternatively (embodiment not shown in FIG. 4), the threshold voltage shifting layer (406) may be deposited on top of an interfacial layer, and a high-k dielectric layer may be deposited on the threshold voltage shifting layer (406).

The semiconductor material (402) can include any suitable semiconducting material. For example, the semiconductor material (402) can include Group IV, Group III-V, or Group II-VI semiconductor material. By way of example, the semiconductor material (402) includes silicon, or more specifically monocrystalline silicon.

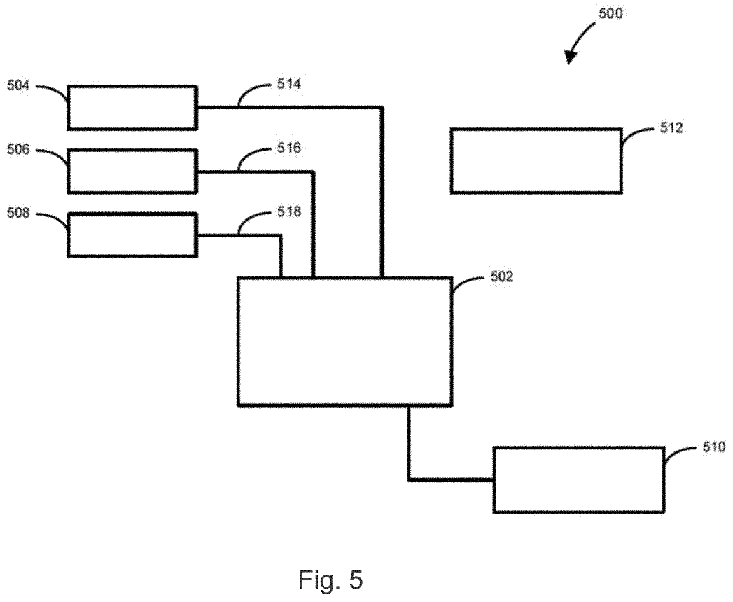

FIG. 5 illustrates a system (500) in accordance with yet additional exemplary embodiments of the disclosure. The system (500) can be used to perform a method as described herein and/or form a structure or device portion as described herein.

In the illustrated example, the system (500) includes one or more reaction chambers (502), a precursor gas source (504), a reactant gas source (506), a purge gas source (508), an exhaust source (510), and a controller (512). The reaction chamber (502) can include any suitable reaction chamber, such as an ALD or CVD reaction chamber.

The precursor gas source (504) can include a vessel and one or more precursors as described herein—alone or mixed with one or more carrier (e.g., inert) gases. The reactant gas source (506) can include a vessel and one or more reactants as described herein—alone or mixed with one or more carrier gases. The purge gas source (508) can include one or more inert gases as described herein. Although illustrated with three gas sources (504)-(508), the system (500) can include any suitable number of gas sources. The gas sources (504)-(508) can be coupled to reaction chamber (502) via lines (514)-(518), which can each include flow controllers, valves, heaters, and the like. The exhaust (510) can include one or more vacuum pumps.

The controller (512) includes electronic circuitry and software to selectively operate valves, manifolds, heaters, pumps and other components included in the system (500). Such circuitry and components operate to introduce precursors, reactants, and purge gases from the respective sources (504)-(508). The controller (512) can control timing of gas pulse sequences, temperature of the substrate and/or reaction chamber, pressure within the reaction chamber, and various other operations to provide proper operation of the system (500). The controller (512) can include control software to electrically or pneumatically control valves to control flow of precursors, reactants and purge gases into and out of the reaction chamber (502). The controller (512) can include modules such as a software or hardware component, e.g., a FPGA or ASIC, which performs certain tasks. A module can advantageously be configured to reside on the addressable storage medium of the control system and be configured to execute one or more processes.

Other configurations of the system (500) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (502). Further, as a schematic representation of a system, many components have been omitted for simplicity of illustration, and such components may include, for example, various valves, manifolds, purifiers, heaters, containers, vents, and/or bypasses.

During operation of the reactor system (500), substrates, such as semiconductor wafers (not illustrated), are transferred from, e.g., a substrate handling system to reaction chamber (502). Once substrate(s) are transferred to the reaction chamber (502), one or more gases from the gas sources (504)-(508), such as precursors, reactants, carrier gases, and/or purge gases, are introduced into reaction chamber (502).

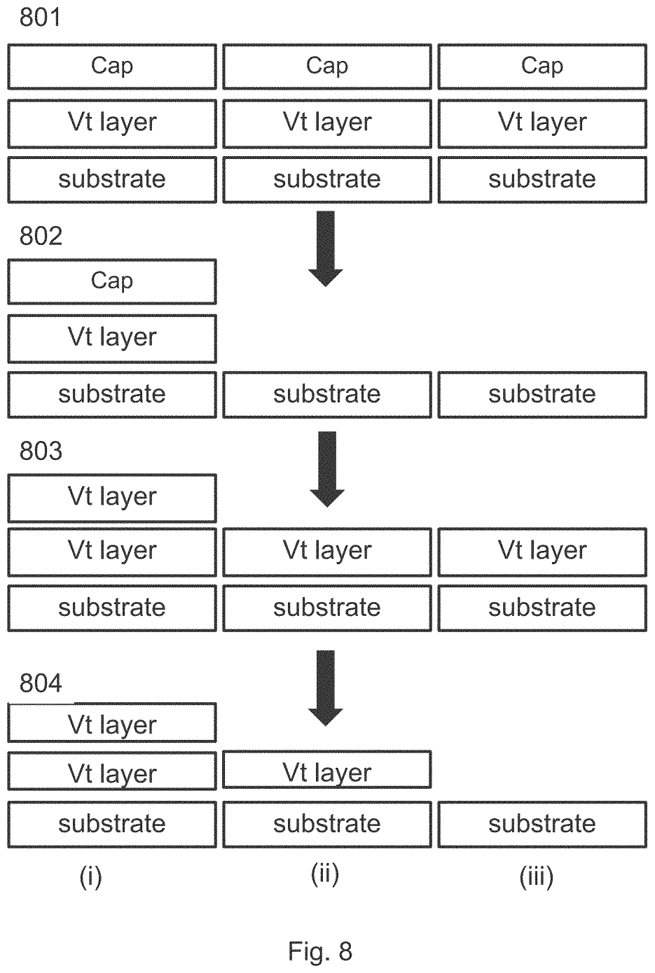

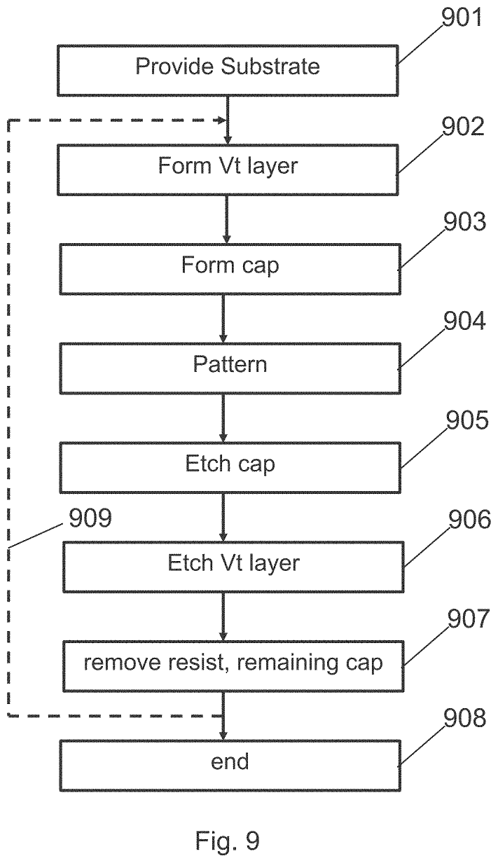

FIGS. 8 and 9 illustrate an aspect of the present disclosure, in particular a method, that can be useful for manufacturing an integrated circuit that comprises transistors having a different threshold voltage. The transistors include metal-oxide-semiconductor (mos) transistor, and can comprise one or more of n-mos transistors and p-mos transistors.

In particular, a first panel (801) in FIG. 8 shows a substrate on which a threshold voltage shifting layer as disclosed herein (Vt layer), for example a layer comprising scandium oxide, has been deposited. The threshold voltage shifting layer can be deposited, for example, on an exposed silicon oxide layer comprised in the substrate. A cap layer is deposited on the threshold voltage shifting layer. The cap layer can serve as a hard mask, and can comprise any suitable material, for example a transition metal nitride such as titanium nitride, or a post transition metal oxide such as aluminum oxide.

In order to arrive at the structure of the first panel (801) of FIG. 8, the first steps (901-903) of the method shown in FIG. 9 can be carried out. In particular, the following steps can be carried out: a step (901) of providing a substrate to a reaction chamber. The substrate comprises a surface at which a silicon oxide layer is exposed. The method then comprises a step (902) of forming a threshold voltage shifting layer. The method then comprises a step (903) of forming a cap layer.

A second panel (802) in FIG. 8 shows how a patterning step using a lithographic technique, for example an extreme ultraviolet lithography patterning step, and a subsequent etch can be used for etching the cap and the threshold voltage shifting layer in some positions of the wafer, and not in other positions of the wafer. The etch can comprise an etch in an aqueous ammonia hydrogen peroxide mixture (APM), followed by an etch in an aqueous mixture of hydrogen peroxide and hydrochloric acid (HPM). Thus, a threshold voltage shifting layer such as a scandium oxide layer can be formed on some parts of the wafer surface, and not on others. This can be advantageously used as part of a process for forming transistors having two sets of threshold voltages.

In order to arrive at a structure of the second panel (802) of FIG. 8, starting from the structure of the first panel (801) of FIG. 8, the following steps in the method of FIG. 9 can be carried out: a patterning step (904) that comprises resist deposition, resist exposure, and resist development; a cap etch step (905) in which the cap is removed using an etchant such as APM that selectively etches the cap and leaves the resist substantially intact; and a step of etching the threshold voltage shifting layer (906) using an etchant such as HPM that selectively etches the threshold voltage shifting layer while leaving the cap and the substrate substantially intact.

A third panel (803) in FIG. 8 shows how a subsequent threshold voltage shifting layer can be formed on the substrate. Such a subsequent threshold voltage shifting layer can be advantageously used for further changing the threshold voltage of at least some of the transistors comprised in an integrated circuit.

In order to arrive at a structure of the third panel (803) of FIG. 8, starting from the structure of the second panel (802) of FIG. 8, the cap and any remaining resist can be removed, and the step (902) of forming a threshold voltage shifting layer can be carried out once more.

A fourth panel (804) in FIG. 8 shows how further patterning and etch steps can result in a substrate comprising three different areas (i,ii,iii): the first area (i) has a relatively thick threshold voltage shifting layer, formed using two distinct steps (902) of forming a threshold voltage shifting layer; the second area (ii) has a relatively thin threshold voltage shifting layer, formed using a single step (902) of forming a threshold voltage shifting layer; and, the third area (iii) does not comprise a threshold voltage shifting layer. In each of the different areas (i,ii,iii), MOS transistors having a different threshold voltage can be made, since they comprise either no threshold voltage shifting layer, a minor amount of threshold voltage shifting layer, or a higher amount of threshold voltage shifting layer.

In order to arrive at a structure according to the fourth panel (904) of FIG. 8, starting from the structure of the third panel (803) of FIG. 8, the following steps in the method of FIG. 9 can be carried out: a patterning step (904) that comprises resist deposition, resist exposure, and resist development; a cap etch step (905) in which the cap is removed using an etchant such as APM that selectively etches the cap and leaves the resist substantially intact; and a step of etching the threshold voltage shifting layer (906) using an etchant such as HPM that selectively etches the threshold voltage shifting layer while leaving the cap and the substrate substantially intact, after which the cap and any remaining resist can be removed, for example using APM.

It shall be understood that steps from forming the threshold voltage shifting layer (902) to removing the resist and the remaining cap (907) can be repeated (909) as needed, e.g. 1 time, 2 times, 3 times, 4 times, or 5 times, in order to arrive at any desirable number of areas with different threshold voltage shifting layer thicknesses. When the method of FIG. 9 has undergone an adequate number of repetitions (909), the method ends (908), and the substrate can proceed to further processing.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing a threshold voltage shifting layer, the method comprising the steps of:
providing a substrate within a reactor chamber, the substrate comprising a surface, the surface comprising a silicon oxide surface, the silicon oxide surface comprising silicon and oxygen;
depositing a threshold voltage shifting layer onto the silicon oxide surface by means of a cyclical deposition process;
wherein the threshold voltage shifting layer comprises an element selected from a lanthanide, yttrium, and scandium;
wherein the cyclical deposition process comprises one or more cycles comprising:
providing a precursor to the reaction chamber in a precursor pulse; and
providing a reactant to the reaction chamber in a reactant pulse;
thus forming a threshold voltage shifting layer on the substrate.

2. The method according to claim 1 wherein the threshold voltage shifting layer comprises scandium, and wherein the precursor comprises a scandium precursor.

3. The method according to claim 2 wherein the scandium precursor comprises one or more cyclopentadienyl ligands and one or more amidinate ligands.

4. The method according to claim 2 wherein the threshold voltage shifting layer comprises a scandium chalcogenide, and wherein the reactant comprises a chalcogenide.

5. The method according to claim 2 wherein the threshold voltage shifting layer comprises scandium oxide, and wherein the reactant comprises an oxygen reactant selected from the list consisting of oxygen, ozone, hydrogen peroxide, and water.

6. The method according to claim 5 wherein the oxygen reactant is water.

7. The method according to claim 2 wherein the threshold voltage shifting layer comprises scandium sulfide, and wherein the reactant comprises a sulfur reactant.

8. The method according to claim 2 wherein the threshold voltage shifting layer comprises scandium selenide, and wherein the reactant comprises a selenium reactant.

9. The method according to claim 1 wherein the threshold voltage shifting layer comprises cerium, and wherein the precursor comprises a cerium precursor.

10. The method according to claim 9 wherein the cerium precursor is selected from the list consisting of cerium diketonates, cerium amidinates, cerium cyclopentadienyls, cerium alkoxides, and cerium alkylsilylamines.

11. The method according to claim 9 wherein the threshold voltage shifting layer comprises a cerium chalcogenide, and wherein the reactant is a chalcogenide reactant comprising a chalcogen.

12. The method according to claim 11 wherein the threshold voltage shifting layer comprises cerium oxide, and wherein the chalcogenide reactant is an oxygen reactant selected from the list consisting of H₂O, O₃, H₂O₂, O₂, oxygen radicals, and oxygen ions.

13. The method according to claim 12 wherein the threshold voltage shifting layer comprises cerium boride, and wherein the reactant comprises a boron reactant selected from the list consisting of hydroboranes; alkylboranes; haloboranes; and amines, ethers, alcohols, thiols, and dialkyl sulfides thereof.

14. The method according to claim 1 wherein the threshold voltage shifting layer comprises yttrium, and wherein the precursor comprises an yttrium precursor.

15. The method according to claim 14 wherein the yttrium precursor comprises an alkyl-substituted cyclopentadienyl ligand and an amidinate ligand.

16. The method according to claim 14 wherein the reactant is selected from the list consisting of H₂O, H₂O₂, O₂, O₃, oxygen radicals, and oxygen ions.

17. The method according to claim 1 wherein the threshold voltage shifting layer has a thickness from at least 0.03 nm to at most 1.0 nm.

18. The method according to claim 1 wherein, after the cyclical deposition process, the substrate is subjected to an anneal in an ambient comprising hydrogen and nitrogen, at a temperature from at least 300° C. to at most 600° C.

19. A system comprising:
one or more reaction chambers;
a precursor gas source comprising a precursor;
a reactant gas source comprising a reactant;
an exhaust source; and
a controller,
wherein the controller is configured to control gas flow into at least one of the one or more reaction chambers to carry out a method according to claim 1.

20. A method for depositing a threshold voltage shifting layer, the method comprising the steps of:
providing a substrate within a reactor chamber, the substrate comprising a surface, the surface comprising a high-k dielectric surface;
depositing a threshold voltage shifting layer onto the high-k dielectric surface by means of a cyclical deposition process;
wherein the threshold voltage shifting layer comprises an element selected from a lanthanide, yttrium, and scandium;
wherein the cyclical deposition process comprises one or more cycles comprising: providing a precursor to the reaction chamber in a precursor pulse; and
providing a reactant to the reaction chamber in a reactant pulse;
thus forming a threshold voltage shifting layer on the substrate.
